(19) United States
(12) Patent Application Publication
(10) Pub. No.: US 2025/0183115 A1
(43) Pub. Date: Jun. 5, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shih-Hao TUNG, Taichung City (TW); Chun-Yu HSIEH, Taichung City (TW); Chun-Wei FANG, Taichung City (TW); Ping-Lin CHANG, Taichung City (TW)

(21) Appl. No.: 18/660,647

(22) Filed: May 10, 2024

(30) Foreign Application Priority Data
Nov. 30, 2023 (TW) 112146616

(51) Int. Cl. H01L 23/367; H01L 21/56; H01L 21/78; H01L 23/00; H01L 23/31; H01L 23/498; H01L 23/538

(52) U.S. Cl. CPC H01L 23/3675; H01L 21/561; H01L 21/78; H01L 23/3142; H01L 23/538; H01L 23/49816; H01L 24/16; H01L 24/48; H01L 2224/16227; H01L 2224/48227

(57) ABSTRACT

An electronic package and a manufacturing method thereof are provided, in which an electronic element and a heat dissipation structure covering the electronic element are disposed on a carrier structure, and the electronic element is covered with a cladding layer. The heat dissipation structure has convex portions facing the carrier structure, so that the bonding area between the heat dissipation structure and the cladding layer is increased via the convex portions, thereby preventing the problem of peeling from occurring to the heat dissipation structure.

### CROSS-REFERENCE TO RELATED APPLICATIONS

The present application is based upon and claims the right of priority to TW Patent Application No. 112146616, filed Nov. 30, 2023, the disclosure of which is hereby incorporated by reference herein in its entirety for all purposes.

### BACKGROUND

### 1. Technical Field

The present disclosure relates to a semiconductor device, and more particularly, to an electronic package that can meet thinning requirements and a manufacturing method thereof.

### 2. Description of Related Art

With the vigorous development of the electronics industry, electronic products are gradually developing towards multi-functional and high-performance trends. Technologies currently used in the field of chip packaging, such as flip-chip package modules such as chip scale package (CSP), wafer-level packaging (WLP), or direct chip attach (DCA), have become the mainstream of packaging.

FIG. 1A to FIG. 1B are schematic cross-sectional views illustrating a manufacturing method of a conventional semiconductor package 1.

As shown in FIG. 1A, a plurality of semiconductor chips 11 are first flip-chip-bonded onto a whole-panel package substrate 10, each of the semiconductor chips 11 is then covered with an encapsulating compound 14, and then a heat dissipation sheet 15 is formed on the encapsulating compound 14 to contact the semiconductor chips 11.

As shown in FIG. 1B, a singulation process is performed along a cutting path S shown in FIG. 1A to obtain a plurality of the semiconductor packages 1, and the heat dissipation sheet 15 can improve the heat dissipation effect of the semiconductor chips 11.

However, in the conventional semiconductor package 1, when the whole-panel heat dissipation sheet 15 (as shown in FIG. 1C) is bonded to the plurality of semiconductor chips 11, the actual bonding area between the heat dissipation sheet 15 and the encapsulating compound 14 is small (only local point-like bonding), so it is easy to cause the problem of peeling of the heat dissipation sheet 15. Especially after the singulation process, delamination will occur from the corners of the heat dissipation sheet 15.

Therefore, how to overcome the above-mentioned problems of the prior art has become an urgent issue to be solved.

### SUMMARY

In view of the various deficiencies of the prior art, the present disclosure provides an electronic package, which comprises: a carrier structure having a circuit layer; an electronic element disposed on the carrier structure and electrically connected to the circuit layer; a heat dissipation structure disposed on the carrier structure and covering the electronic element, wherein the heat dissipation structure has a plurality of convex portions facing the carrier structure; and a cladding layer formed on the carrier structure and covering the electronic element.

The present disclosure further provides a method of manufacturing an electronic package, the method comprises: disposing an electronic element on a carrier structure having a circuit layer, wherein the electronic element is electrically connected to the circuit layer; disposing a heat dissipation structure on the carrier structure to cover the electronic element, wherein the heat dissipation structure has a plurality of convex portions facing the carrier structure; forming a cladding layer between the carrier structure and the heat dissipation structure to cover the electronic element; and performing a singulation process along a cutting path, wherein the cutting path passes through the plurality of convex portions.

In the aforementioned electronic package and method, one of the convex portions is located at at least one corner of the cladding layer.

In the aforementioned electronic package and method, the heat dissipation structure is made of metal. For example, the heat dissipation structure includes a heat dissipation sheet, and the convex portions are disposed on the heat dissipation sheet.

In the aforementioned electronic package and method, the heat dissipation structure includes a heat dissipation sheet covering the electronic element, and a support leg connected to the heat dissipation sheet and disposed on the carrier structure.

In the aforementioned electronic package and method, the present disclosure further comprises conductive elements electrically connected to the carrier structure.

As can be seen from the above, in the electronic package and manufacturing method thereof of the present disclosure, compared to the prior art, the bonding area between the heat dissipation structure and the cladding layer can be increased via the design of providing convex portions on the heat dissipation structure, thereby effectively preventing the problem of peeling from occurring to the heat dissipation structure during the singulation process. Especially after the singulation process, the corners of the heat dissipation structure are clamped by the convex portions to strengthen the bonding of the heat dissipation structure and the cladding layer.

### BRIEF DESCRIPTION OF THE DRAWINGS

FIG. 1A to FIG. 1B are schematic cross-sectional views illustrating a manufacturing method of a conventional semiconductor package.

FIG. 1C is a schematic view of a whole-panel heat dissipation sheet of the conventional semiconductor package.

FIG. 2A to FIG. 2E are schematic cross-sectional views illustrating a manufacturing method of an electronic package according to the present disclosure, wherein FIG. 2C is a schematic partial top view.

FIG. 3A and FIG. 3B are schematic cross-sectional views of different embodiments of FIG. 2C.

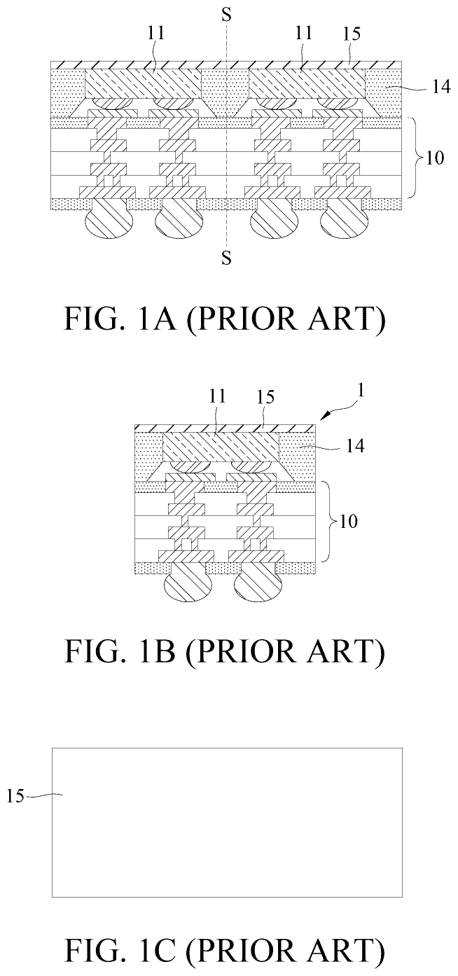

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

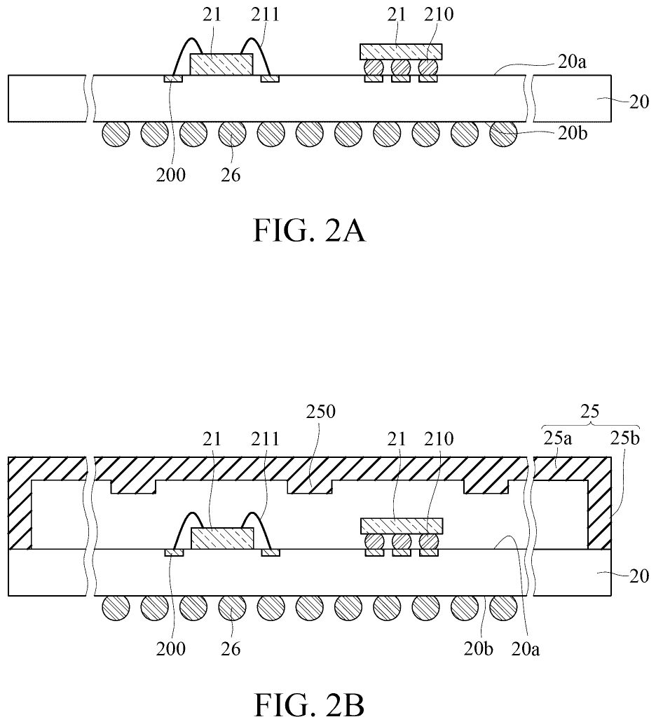

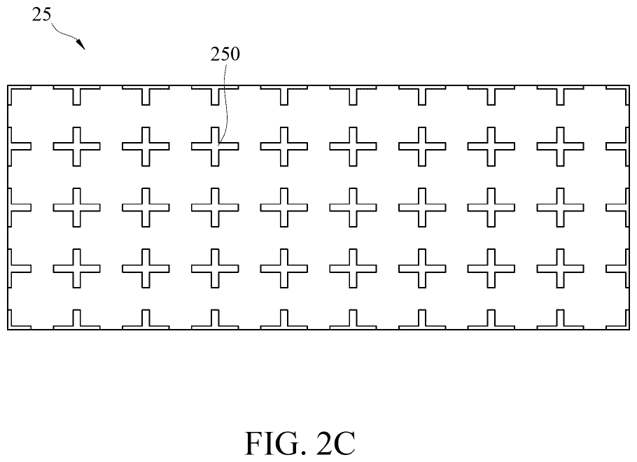

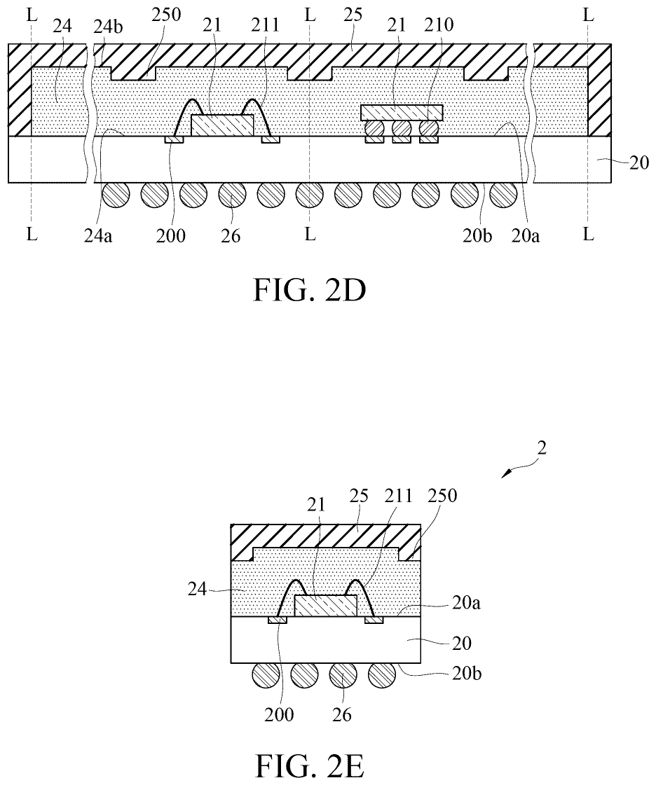

FIG. 2A to FIG. 2E are schematic cross-sectional views illustrating a manufacturing method of an electronic package 2 of the present disclosure, wherein FIG. 2C is a schematic partial top view.

As shown in FIG. 2A, a whole-panel carrier structure 20 is provided, which has a first side 20a and a second side 20b opposing the first side 20a, and electronic elements 21 separated from each other are disposed on the first side 20a of the carrier structure 20. Then, a plurality of conductive elements 26 such as solder balls are formed on the second side 20b of the carrier structure 20 for subsequent connection of electronic devices (not shown) such as package structures or other structures (such as chips).

The carrier structure 20 is a circuit structure with a core layer or a coreless circuit structure, wherein at least one circuit layer 200, such as a fan-out redistribution layer (RDL), is formed in an insulating layer.

In one embodiment, the material for forming the circuit layer 200 is copper, and the material for forming the insulating layer is dielectric material such as polybenzoxazole (PBO), polyimide (PI), prepreg (PP), or the like. It should be understood that the carrier structure 20 may also be other types of chip-carrying carriers, such as an organic board, a wafer, or other types of board having metal routings, and the present disclosure is not limited to as such.

The electronic element 21 is an active element, a passive element, or a combination of the active element and the passive element. The active element is, for example, a semiconductor chip, and the passive element is, for example, a resistor, a capacitor, or an inductor.

In one embodiment, the electronic element 21 is a semiconductor chip, and the electronic element 21 is disposed on the carrier structure 20 in a flip-chip manner via a plurality of conductive bumps 210 made of solder material and is electrically connected to the circuit layer 200 of the first side 20a; alternatively, the electronic element 21 can be electrically connected to the circuit layer 200 of the first side 20a via a plurality of bonding wires 211 in a wire-bonding manner. However, the manner in which the electronic element 21 is electrically connected to the carrier structure 20 is not limited to the above.

In addition, an under-bump metallurgy (UBM) layer (not shown) can be formed on the outermost circuit layer 200 of the second side 20b of the carrier structure 20 as needed to facilitate the bonding of the conductive elements 26.

As shown in FIG. 2B, a heat dissipation structure 25 is provided and disposed on the first side 20a of the carrier structure 20, so that the heat dissipation structure 25 covers the electronic elements 21.

In one embodiment, the heat dissipation structure 25 includes a heat dissipation sheet 25a and a support leg 25b connected to the heat dissipation sheet 25a, wherein the support leg 25b is disposed on the first side 20a of the carrier structure 20, so that the heat dissipation sheet 25a covers the electronic elements 21. For example, the heat dissipation structure 25 is made of material such as gold (Au), silver (Ag), copper (Cu), nickel (Ni), iron (Fe), aluminum (Al), stainless steel (steel use stainless or SUS), and other metals.

Furthermore, the heat dissipation sheet 25a has a plurality of convex portions 250 (e.g., protrusions) facing the carrier structure 20. For example, the shape of the convex portion 250 is a cross, as shown in FIG. 2C, which corresponds to a cutting path L shown in FIG. 2D.

As shown in FIG. 2D, a cladding layer 24 is formed on the first side 20a of the carrier structure 20, wherein the cladding layer 24 is filled between the heat dissipation sheet 25a and the first side 20a of the carrier structure 20, so that the cladding layer 24 covers the electronic elements 21.

The cladding layer 24 has a first surface 24a and a second surface 24b opposing the first surface 24a, so that the first surface 24a of the cladding layer 24 is bonded onto the first side 20a of the carrier structure 20.

In one embodiment, the cladding layer 24 is made of insulating material, such as polyimide (PI), dry film, epoxy resin, or molding compound, and the cladding layer 24 can be formed on the first side 20a of the carrier structure 20 by lamination or molding.

As shown in FIG. 2E, a singulation process is performed along the cutting path L shown in FIG. 2D to remove the support leg 25b, so as to obtain the electronic package 2 of the present disclosure.

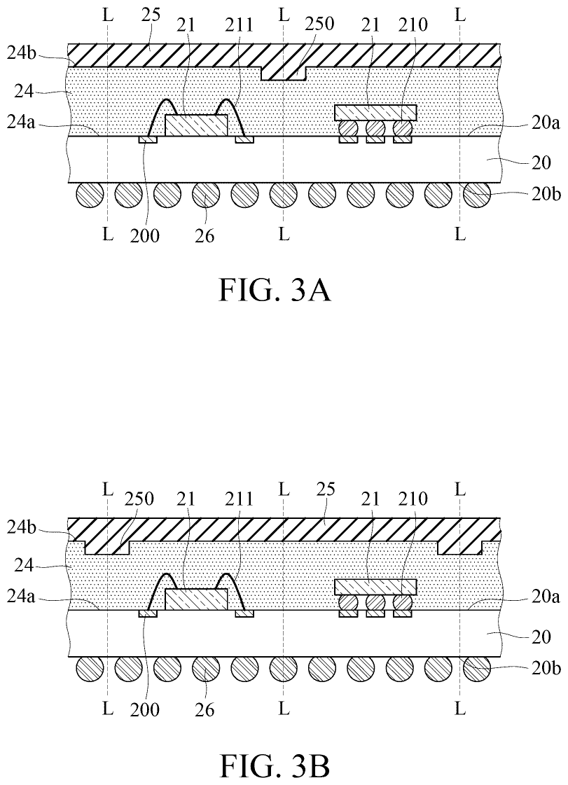

In one embodiment, the plurality of convex portions 250 are arranged on the cutting path L. However, in other embodiments, as shown in FIG. 3A and FIG. 3B, the convex portions 250 may not be arranged on part of the cutting path L.

Therefore, in the manufacturing method of the electronic package 2 of the present disclosure, the heat dissipation structure 25 having the plurality of convex portions 250 on one side is provided, wherein, via the design of the cutting path L corresponding to the convex portions 250, the bonding area of the heat dissipation structure 25 and the cladding layer 24 can be increased when the whole-panel heat dissipation structure 25 (as shown in FIG. 2D) is bonded onto multiple electronic elements 21, thereby effectively preventing the heat dissipation structure 25 from the problem of peeling. Therefore, compared with the prior art, in the manufacturing method of the present disclosure, the corners of the heat dissipation structure 25 are clamped by the convex portions 250 after the singulation process, so that the problem of peeling does not occur.

The present disclosure also provides an electronic package 2, which comprises: a carrier structure 20 having a circuit layer 200, at least one electronic element 21, a cladding layer 24, and a heat dissipation structure 25.

The electronic element 21 is disposed on the carrier structure 20 and is electrically connected to the circuit layer 200.

The heat dissipation structure 25 is disposed on the carrier structure 20, so that the heat dissipation structure 25 covers the electronic element 21, wherein the heat dissipation structure 25 has convex portions 250 facing the carrier structure 20.

The cladding layer 24 is formed on the carrier structure 20 and covers the electronic element 21.

In one embodiment, the convex portion 250 is located at at least one corner of the cladding layer 24.

In one embodiment, the heat dissipation structure 25 is made of metal.

In one embodiment, the heat dissipation structure 25 includes a heat dissipation sheet 25a, and the convex portions 250 are disposed on the heat dissipation sheet 25a.

In one embodiment, the electronic package 2 further comprises conductive elements 26 electrically connected to the circuit layer 200.

To sum up, in the electronic package and manufacturing method thereof of the present disclosure, via the design of providing convex portions on one side of the heat dissipation structure for connecting the cladding layer, the bonding area between the heat dissipation structure and the cladding layer can be increased, thereby effectively preventing the heat dissipation structure from the problem of peeling.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a circuit layer;
an electronic element disposed on the carrier structure and electrically connected to the circuit layer;
a heat dissipation structure disposed on the carrier structure and covering the electronic element, wherein the heat dissipation structure has a plurality of convex portions facing the carrier structure; and
a cladding layer formed on the carrier structure and covering the electronic element.

2. The electronic package of claim 1, wherein one of the convex portions is located at at least one corner of the cladding layer.

3. The electronic package of claim 1, wherein the heat dissipation structure is made of metal.

4. The electronic package of claim 1, wherein the heat dissipation structure includes a heat dissipation sheet, and the convex portions are disposed on the heat dissipation sheet.

5. The electronic package of claim 1, further comprising conductive elements electrically connected to the carrier structure.

6. A method of manufacturing an electronic package, comprising:
disposing an electronic element on a carrier structure having a circuit layer, wherein the electronic element is electrically connected to the circuit layer;
disposing a heat dissipation structure on the carrier structure to cover the electronic element, wherein the heat dissipation structure has a plurality of convex portions facing the carrier structure;
forming a cladding layer between the carrier structure and the heat dissipation structure to cover the electronic element; and
performing a singulation process along a cutting path, wherein the cutting path passes through the plurality of convex portions.

7. The method of claim 6, wherein one of the convex portions is located at at least one corner of the cladding layer after the singulation process.

8. The method of claim 6, wherein the heat dissipation structure is made of metal.

9. The method of claim 6, wherein the heat dissipation structure includes a heat dissipation sheet covering the electronic element, and a support leg connected to the heat dissipation sheet and disposed on the carrier structure.

10. The method of claim 6, further comprising forming a plurality of conductive elements on another side of the carrier structure opposite to a side of the carrier structure on which the electronic element is disposed.
